(19) United States
(12) Patent Application Publication
(10) Pub. No.: US 2025/0160186 A1
(43) Pub. Date: May 15, 2025

(54) DISPLAY DEVICE AND METHOD FOR FABRICATING THE SAME

(71) Applicant: Samsung Display Co., LTD., Yongin-si (KR)

(72) Inventors: Joon Ik LEE, Yongin-si (KR); Dong Hwan KIM, Yongin-si (KR); Jun Woo YOU, Yongin-si (KR); Chang Moo LEE, Yongin-si (KR)

(73) Assignee: Samsung Display Co., LTD., Yongin-si (KR)

(21) Appl. No.: 18/738,293

(22) Filed: Jun. 10, 2024

(30) Foreign Application Priority Data
Nov. 14, 2023 (KR) 10-2023-0157322

(51) Int. Cl. H10K 59/80; H10K 59/40

(52) U.S. Cl. CPC H10K 59/8792; H10K 59/40; H10K 59/873

(57) ABSTRACT

The disclosure relates to a display device, and more particularly, to a display device capable of minimizing a light leakage phenomenon to improve an image quality, and a method for fabrication thereof. A display device includes a base substrate; a display element disposed on the base substrate in a display area; an encapsulation layer on the display element; and a light shielding layer disposed on the encapsulation layer in a non-display area.

### CROSS-REFERENCE TO RELATED APPLICATION

This application claims priority from and benefits of Korean Patent Application No. 10-2023-0157322 under 35 U.S.C. § 119, filed on Nov. 14, 2023 in the Korean Intellectual Property Office (KIPO), the contents of which in its entirety are incorporated herein by reference.

### BACKGROUND

### 1. Technical Field

The disclosure relates to a display device, and more particularly, to a display device capable of minimizing a light leakage phenomenon to improve an image quality, and a method for fabrication thereof.

### 2. Description of the Related Art

Various types of electronic devices, including display modules, are used to provide image information, and electronic devices may include electronic modules that receive external signals or provide output signals to the outside. For example, electronic modules may include camera modules, etc., and the demands for display devices that can obtain high-quality captured images are increasing.

### SUMMARY

Aspects of the disclosure provide a display device capable of minimizing a light leakage phenomenon to improve an image quality, and a method for fabrication thereof.

According to an embodiment of the disclosure, the light leakage phenomenon can be minimized. Therefore, the image quality can be improved.

According to an embodiment of the disclosure, a displayed device comprises a base substrate; a display element disposed on the base substrate in a display area; an encapsulation layer on the display element; and a light shielding layer disposed on the encapsulation layer in a non-display area.

In an embodiment, the light shielding layer may be disposed along the edge of the upper surface of the base substrate and the edge of the upper surface of the encapsulation layer.

In an embodiment, in plan view, the light shielding layer may surround at least one of the encapsulation layer, the display element, and the display area.

In an embodiment, in plan view, the light shielding layer may have a closed curve shape surrounding at least one of the encapsulation layer, the display element, and the display area.

In an embodiment, in a non-display area, the light shielding layer may be disposed directly on the encapsulation layer.

In an embodiment, in the non-display area, the light shielding layer may be in contact with the encapsulation layer.

In an embodiment, the interface between the light shielding layer and the encapsulation layer may have a round shape.

In an embodiment, the display device may further comprise an adhesive layer on the encapsulation layer and the light shielding layer.

In an embodiment, the display device may further comprise a touch sensing part disposed between the encapsulation layer and the adhesive layer, and disposed between the encapsulation layer and the light shielding layer.

In an embodiment, the light shielding layer may be in contact with the touch sensing part.

In an embodiment, the display device may further comprise a first planarization layer between the encapsulation layer and the touch sensing part.

In an embodiment, the display device may further comprise a second planarization layer between the touch sensing part and the adhesive layer, and disposed between the touch sensing part and the light shielding layer.

In an embodiment, the display device may further comprise a protective substrate on the adhesive layer.

In an embodiment, the display device may further comprise a polarization plate on the protective substrate.

In an embodiment, the light shielding layer may be disposed on the protective substrate to overlap the edge of the encapsulation layer.

In an embodiment, the light shielding layer may be disposed directly on the protective substrate.

In an embodiment, in plan view, the light shielding layer may surround the polarization plate.

In an embodiment, the light shielding layer may comprise a first light shielding layer disposed directly on the encapsulation layer; and a second light shielding layer disposed directly on the protective substrate to overlap the encapsulation layer.

In an embodiment, the display device may further comprise a dam disposed on the base substrate to overlap the light shielding layer in the non-display area.

In an embodiment, a portion of the encapsulation layer may be disposed between the dam and the light shielding layer.

In an embodiment, the light shielding layer may include a black pigment or an organic black pigment.

In an embodiment, the light shielding layer may have a square ring shape with four sides.

In an embodiment, the four sides may comprise a first side adjacent to a pad area of the base substrate; a second side disposed to face the first side; a third side connected to an end of the first side and an end of the second side; and a fourth side disposed to face the third side, and connected to another end of the first side and another end of the second side.

In an embodiment, a width of the first side and a width of the second side may be substantially equal to each other, and a width of the third side and a width of the fourth side may be different.

According to an embodiment of the disclosure, a method for fabricating a display device, comprises placing a display element on a base substrate in a display area; placing an encapsulation layer on the display element; and placing a light shielding layer on the encapsulation layer in a non-display area.

In an embodiment, the light shielding layer may be disposed along the edge of the upper surface of the base substrate and the edge of the upper surface of the encapsulation layer.

In an embodiment, in plan view, the light shielding layer may surround at least one of the encapsulation layer, the display element, and the display area.

In an embodiment, in plan view, the light shielding layer may have a closed curve shape surrounding at least one of the encapsulation layer, the display element, and the display area.

In an embodiment, in the non-display area, the light shielding layer may be disposed directly on the encapsulation layer.

In an embodiment, in the non-display area, the light shielding layer may be in contact with the encapsulation layer.

In an embodiment, the interface between the light shielding layer and the encapsulation layer may have a round shape.

According to an embodiment of the disclosure, permeation to the display device can be prevented.

The advantages and effects of the disclosure are not limited to the above-described effects and other effects which are not described herein will become apparent to those skilled in the art from the following description.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to an embodiment;

FIG. 2 is a schematic cross-sectional view taken along line I-I′ of FIG. 1;

FIGS. 3 to 6 are schematic drawings for describing a method of manufacturing a display device according to an embodiment;

FIG. 7 is schematic cross-sectional view of a display device according to an embodiment;

FIG. 8 is a schematic cross-sectional view of a display device according to another embodiment;

FIG. 9 is a schematic cross-sectional view of a display device according to still another embodiment;

FIG. 10 is a schematic cross-sectional view of a display device according to still another embodiment;

FIG. 11 is a schematic cross-sectional view of a display device according to still another embodiment; and

FIG. 12 is a schematic cross-sectional view of a display device according to still another embodiment.

### DETAILED DESCRIPTION OF THE EMBODIMENTS

Advantages and features of the disclosure and methods to achieve them will become apparent from the descriptions of embodiments hereinbelow with reference to the accompanying drawings. However, the disclosure is not limited to embodiments disclosed herein but may be implemented in various different ways. The embodiments are provided for making the disclosure of the disclosure more thorough and for conveying the scope of the disclosure to those skilled in the art. It is to be noted that the scope of the disclosure is defined only by the claims.

As used herein, a phrase “an element A on an element B” refers to that the element A may be disposed directly on the element B and/or the element A may be disposed indirectly on the element B via another element C. Like reference numerals and/or reference characters denote like elements throughout the descriptions. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the disclosure.

Features of various embodiments of the disclosure may be combined partially or totally. As will be clearly appreciated by those skilled in the art, technically various interactions and operations are possible. Various embodiments can be practiced individually or in combination.

Hereinafter, embodiments of the disclosure will be described with reference to the accompanying drawings.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

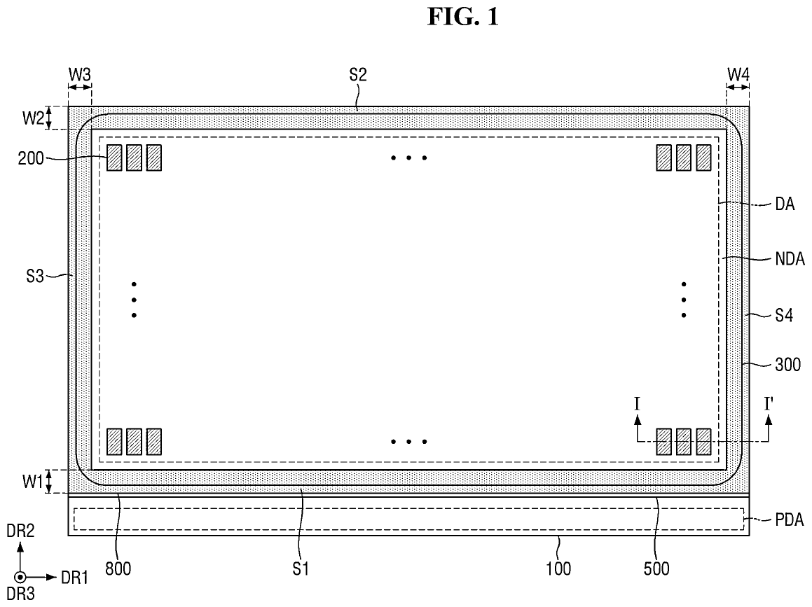

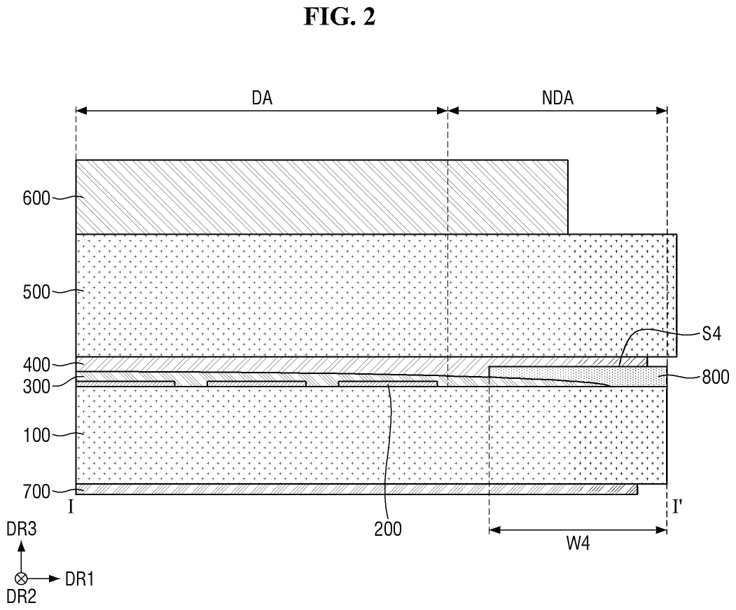

FIG. 1 is a schematic plan view of a display device according to an embodiment, and FIG. 2 is a schematic cross-sectional view taken along line I-I′ of FIG. 1.

As illustrated in FIGS. 1 and 2, a display device according to an embodiment may include a passivation layer 700, a base substrate 100, one or more display elements 200, an encapsulation layer 300, an adhesive layer 400, a protective substrate 500, a polarization plate 600, and/or a light shielding layer 800.

The passivation layer 700 may protect the bottom surface of the base substrate 100 as well as performing a shielding function. For example, the passivation layer 700 may prevent a scratch from occurring on the bottom surface of the base substrate 100. For this, the passivation layer 700 may be disposed on the bottom surface of the base substrate 100.

The base substrate 100 may be disposed on the passivation layer 700. The base substrate 100 may be a flexible substrate which can be bent, folded and/or rolled. For example, the base substrate 100 may include a polymer resin such as polyimide (PI), but is not limited thereto. For another example, the base substrate 100 may include a glass material or a metal material. Here, the glass may be a flexible or rigid glass, and the metal may be a flexible or rigid metal. According to a display device according to an embodiment, the base substrate 100 may be, for example, an ultra-thin glass. The ultra-thin glass may have, for example, a very thin thickness through an etching process. Here, the thickness of the base substrate 100 may mean a dimension in a third direction DR3.

The display elements 200 may be disposed on the base substrate 100. For example, the display elements 200 may be disposed on the base substrate 100 in the third direction DR3. The display elements 200 may be disposed on a display area DA of the base substrate 100. The display device 200 may include a light emitting element. The light emitting element may include an anode electrode, a light emitting layer, and a cathode electrode. The anode electrode, the light emitting layer, and the cathode electrode may be sequentially stacked in the third direction DR3. For example, a light emitting layer may be stacked on the anode electrode in the third direction DR3, and a cathode electrode may be disposed on the light emitting layer in the third direction DR3.

The light emitting layer may be an organic light emitting layer including an organic material. The light emitting layer may include a hole transporting layer, an organic light emitting layer, and an electron transporting layer. In case that the anode electrode receives a voltage (e.g., a predetermined or selectable voltage) through a thin film transistor and the cathode electrode receives the cathode voltage, holes and electrons may be transferred to the organic light emitting layer through the hole transporting layer and the electron transporting layer, respectively, and may be combined with each other to emit light in the organic light emitting layer.

In another example, the light emitting elements may include a quantum dot light emitting diode including a quantum dot light emitting layer, an inorganic light emitting diode including an inorganic semiconductor, or a micro light emitting diode.

The encapsulation layer 300 may be disposed on the light emitting elements 200. For example, the encapsulation layer 300 may be disposed on the light emitting elements 200 in the third direction DR3. The encapsulation layer 300 may cover the top and side surfaces of each of the light emitting elements 200 and protect the light emitting elements 200. The encapsulation layer 300 may include at least one inorganic layer and at least one organic layer for encapsulating the light emitting elements 200. For example, the encapsulation layer 300 may include a first inorganic layer, an organic layer, and a second inorganic layer sequentially stacked in a third direction on the base substrate 100.

The light shielding layer 800 may be disposed on the encapsulation layer 300 and the base substrate 100. As illustrated in FIGS. 1 and 2, the light shielding layer 800 may be disposed in a non-display area NDA of the base substrate 100. From a plan view as illustrated in FIG. 1, the light shielding layer 800 may have a shape of a closed curve surrounding the display area DA of the base substrate 100. For example, as illustrated in FIGS. 1 and 2, the light shielding layer 800 may have a shape of a closed curve surrounding at least one of the display area DA, the display elements 200, and the encapsulation layer 300 in the non-display area NDA.

As illustrated in FIG. 2, the light shielding layer 800 may be disposed on an edge of the upper surface of the base substrate 100. For example, the light shielding layer 800 may be disposed on the base substrate 100 in the third direction DR3, and the light shielding layer 800 may be disposed along the edge of the upper surface of the base substrate 100. The upper surface of the base substrate 100 may be the surface on which the above-described display elements 200 are disposed.

The light shielding layer 800 may be disposed along the edge of the upper surface of the base substrate 100 and the edge of the upper surface of the encapsulation layer 300. The light shielding layer 800 may face the edge of the upper surface of the base substrate 100 and the edge of the upper surface of the encapsulation layer 300 in the third direction DR3. At the edge of the upper surface of the base substrate 100, the light shielding layer 800 may be in contact with (or be in direct contact with) the upper surface of the base substrate 100. At the edge of the upper surface of the encapsulation layer 300, the light shielding layer 800 may be in contact with (or be in direct contact with) the encapsulation layer 300. The edge of the encapsulation layer 300 may be disposed between the base substrate 100 and the light shielding layer 800.

As illustrated in FIG. 2, the light shielding layer 800 may be disposed directly on the base substrate 100 and directly on the encapsulation layer 300 in the non-display area NDA.

As illustrated in FIG. 2, an interface between the light shielding layer 800 and the encapsulation layer 300 may have a round shape.

The light shielding layer 800 may include a light absorbing material (or an opaque material). For example, the light shielding layer 800 may include an inorganic black pigment or an organic black pigment. The inorganic black pigment may be a carbon black and the organic black pigment may include at least one of Lactam Black, Perylene Black, and Aniline Black, but the disclosure is not limited thereto. For example, the light shielding layer 800 may be made of (or include) a material containing any one of colors other than black. According to an embodiment, the light shielding layer 800 may include an opaque white material.

As illustrated in FIG. 1, the light shielding layer 800 may have a square ring shape with four sides. For example, the four sides may include a first side S1, a second side S2, a third side S3, and a fourth side S4. The first side S1 may be disposed adjacent to a pad area PDA of the base substrate. The second side S2 may be arranged to face the first side S1 in a second direction DR2. The third side S3 may be connected to an end of the first side S1 and an end of the second side S2. The fourth side S4 may be disposed to face the third side S3 in a first direction DR1, and may be connected to another end of the first side S1 and another end of the second side S2. The first to fourth sides S1 to S4 may be integrally formed or integral with each other.

Sides of the light shielding layer 800 facing each other may have the same width. For example, the first side S1 and the second side S2 facing each other in the second direction DR2 may have the same width. In other words, a width W1 of the first side S1 and a width W2 of the second side S2 may be the same. The third side S3 and the fourth side S4 facing each other in the first direction DR1 may have the same width. In other words, a width W3 of the third side S3 and a width W4 of the fourth side S4 may be the same. However, the disclosure is not limited thereto, and the width W3 of the third side S3 and the width W4 of the fourth side S4 may be different.

The light shielding layer 800 may prevent light leakage phenomenon, in which light provided from the display elements 200 is emitted to the edge of the display device. For example, light from display elements 200 that are close to the non-display area NDA of the base substrate 100 among the display elements 200 may be emitted outside through the edge of the display device (e.g., the non-display area NDA of the base substrate 100), and light shielding layer 800 described above can prevent light of the display elements 200 from being emitted to the outside through the edge of the display device. Accordingly, image quality of the display device can be improved. Since the light shielding layer 800 covers (or overlap) the edge of the encapsulation layer 300 that is susceptible to encapsulation, the light shielding layer 800 can prevent air and moisture from permeating into the display elements 200 through the edge of the encapsulation layer 300.

The adhesive layer 400 may be disposed on the light shielding layer 800 and the encapsulation layer 300. For example, the adhesive layer 400 may be disposed on the center of the encapsulation layer 300 in the display area DA of the base substrate 100, and the adhesive layer 400 may be disposed on the edge of the encapsulation layer 300 and the light shielding layer 800 in the non-display area NDA of the base substrate 100.

The adhesive layer 400 may be in contact with the light shielding layer 800 and the encapsulation layer 300. The adhesive layer 400 may adhere the encapsulation layer 300 and the protective substrate 500 to be described below, and adhere the light shielding layer 800 and the protective substrate 500. For example, the adhesive layer 400 may include a pressure sensitive adhesive such as an optically clear resin (OCR) or an optically clear adhesive (OCA).

The protective substrate 500 may be disposed on the adhesive layer 400. The protective substrate 500 may be a flexible substrate which can be bent, folded and/or rolled. For example, the protective substrate 500 may include a polymer resin such as polyimide (PI), but is not limited thereto. For another example, the protective substrate 500 may include a glass material or a metal material. Here, the glass may be a flexible or rigid glass, and the metal may be a flexible or rigid metal.

The protective substrate 500 may overlap the base substrate 100. For example, the entire protective substrate 500 may be overlapped by the base substrate 100. The protective substrate 500 described above may have a smaller area than the base substrate 100. For example, the area of the protective substrate 500 in a first direction DR1 and a second direction DR2 may be greater than the area of the base substrate 100 in the first direction DR1 and the second direction DR2. In plan view, the edge of the protective substrate 500 may be surrounded by the edge of the base substrate 100. In other words, the edge of the base substrate 100 may extend further in the first direction DR1 and the second direction DR2 than the edge of the protective substrate 500. Like described above, since the area of the protective substrate 500 is smaller than the area of the base substrate 100, dead space of the display device may be minimized. The length of the protective substrate 500 in the first direction DR1 may be greater than the length of the base substrate 100 in the first direction DR1 as illustrated in FIG. 2, and the length of the protective substrate 500 in the second direction DR1 may be smaller than the length of the base substrate 100 in the first direction DR1 as illustrated in FIG. 1.

The polarization plate 600 may be disposed on the protective substrate 500. For example, the polarization plate 600 may be disposed on the protective substrate 500 in the third direction DR3. The polarization plate 600 may include a linear polarization layer and at least one retardation layer. The linear polarization layer may be an optical layer that linearly polarizes light provided from the outside in one direction. The retardation layer may be a N/2 retardation layer and a 2/4 retardation layer. The polarization plate 600 may function to reduce reflection caused by external light.

The polarization plate 600 may overlap the base substrate 100. For example, the entire polarization plate 600 may be overlapped by the base substrate 100. The base substrate 100 described above may have a greater area than the polarization plate 600. For example, the area of the base substrate 100 in the first direction DR1 and the second direction DR2 may be greater than the area of the polarization plate 600 in the first direction DR1 and the second direction DR2. In plan view, the edge of the base substrate 100 may surround the edge of the polarization plate 600. In other words, the edge of the base substrate 100 may extend further in the first direction DR1 and the second direction DR2 than the edge of the polarization plate 600.

The polarization plate 600 may overlap the protective substrate 500. For example, the entire polarization plate 600 may overlap the protective substrate 500. The protective substrate 500 described above may have an area greater than the polarization plate 600. For example, the area of the protective substrate 500 in the first direction DR1 and the second direction DR2 may be larger than the area of the polarization plate 600 in the first direction DR1 and the second direction DR2. From a plan view, the edge of the polarization plate 600 may surround the edge of the protective substrate 500. In other words, the edge of the protective substrate 500 may extend further in the first direction DR1 and the second direction DR2 than the edge of the polarization plate 600.

Although not illustrated, a color filter may be further disposed between the protective substrate 500 and the polarization plate 600.

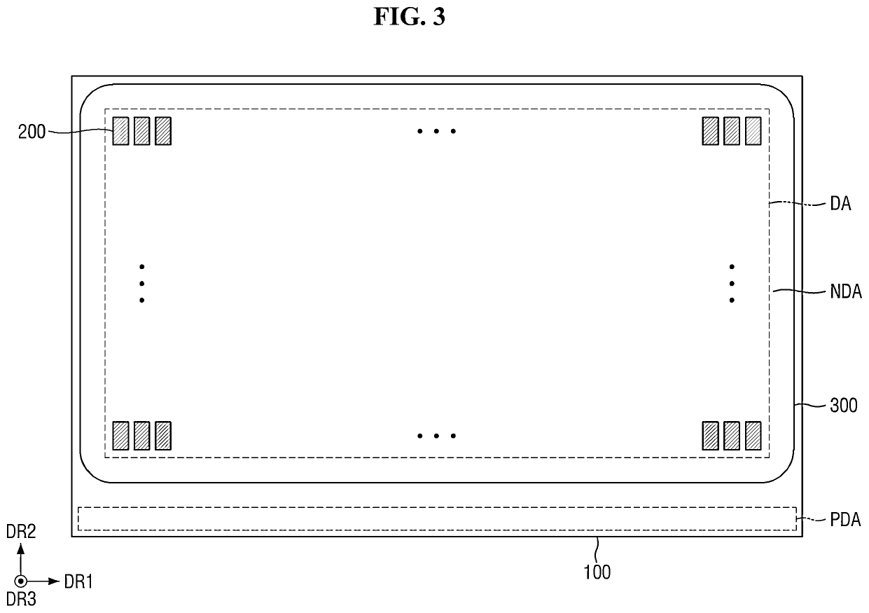

Hereinafter, a method of manufacturing a display device according to an embodiment will be described with reference to FIG. 2 described above and FIGS. 3 to 6 as follows.

FIGS. 3 to 6 are schematic drawings for describing a method of manufacturing a display device according to an embodiment.

First, as illustrated in FIGS. 3 and 2, display elements 200 may be disposed on a display area DA of a base substrate 100, and an encapsulation layer 300 may be disposed on the display area DA and a non-display area NDA of the base substrate 100 to cover the display elements 200.

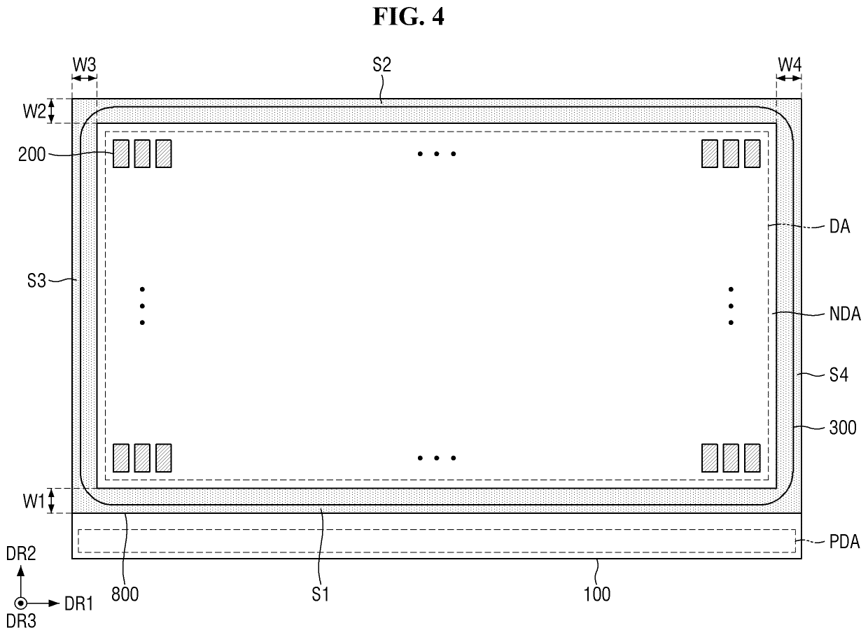

Subsequently, as illustrated in FIGS. 4 and 2, a light shielding layer 800 may be disposed to cover the edge of the encapsulation layer 300 in the non-display area NDA of the base substrate 100. For example, the light shielding layer 800 may be formed by jetting a material (e.g., organic pigment) used in the light shielding layer 800 by using an inkjet equipment. For example, organic pigment sprayed from a nozzle of the inkjet equipment may be formed along the edge of the upper surface of the base substrate 100 and the edge of the upper surface of the encapsulation layer 300. In an embodiment, the light shielding layer 800 may be formed, for example, by applying a material (e.g., organic pigment) used in the light shielding layer 800 by using the inkjet equipment. For example, the organic pigment discharged from a head of the inkjet equipment may be formed along the edge of the upper surface of the base substrate 100 and the edge of the upper surface of the encapsulation layer 300. In an embodiment, the light shielding layer 800 may be formed, for example, by applying the organic pigment using an electrohydrodynamic (EHD) printing equipment. For example, organic pigment discharged from a nozzle of the electrohydrodynamic (EHD) printing equipment may be formed along the edge of the base substrate 100 and the edge of the encapsulation layer 300.

Subsequently, the organic pigment formed along the edge of the base substrate 100 and the edge of the encapsulation layer 300 may be cured through a curing process. The curing process may include, for example, at least one of an ultraviolet curing process, a heat curing process, and a room temperature curing process. In other words, the organic pigment can be cured by applying ultraviolet rays or heat to the organic pigment. As another example, organic pigments may be naturally cured by being left at room temperature for a certain period of time. The cured organic pigment may function as the light shielding layer 800.

Subsequently, as illustrated in FIG. 2, an adhesive layer 400 may be disposed on the light shielding layer 800 and the encapsulation layer 300.

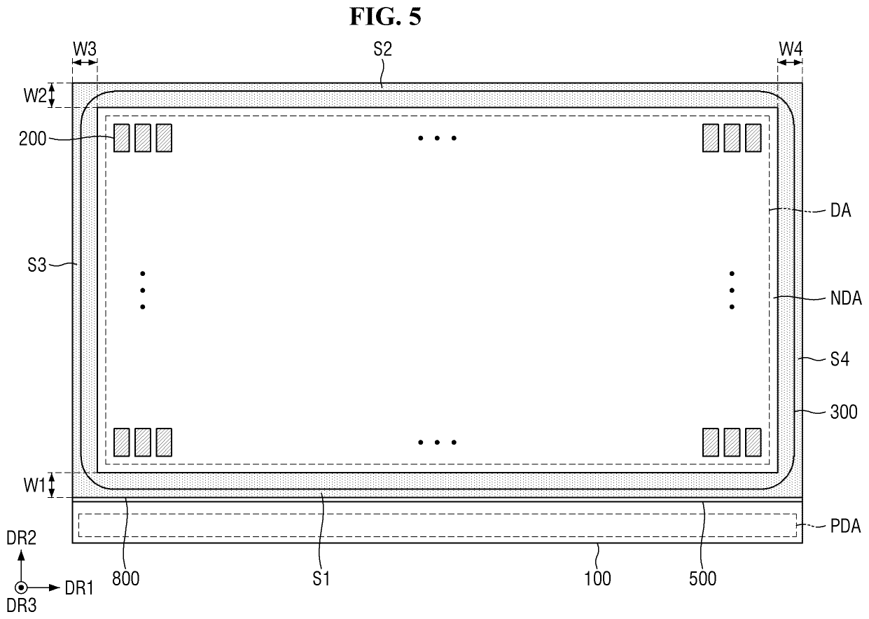

Next, as illustrated in FIGS. 5 and 2, a protective substrate 500 may be disposed on the adhesive layer 400.

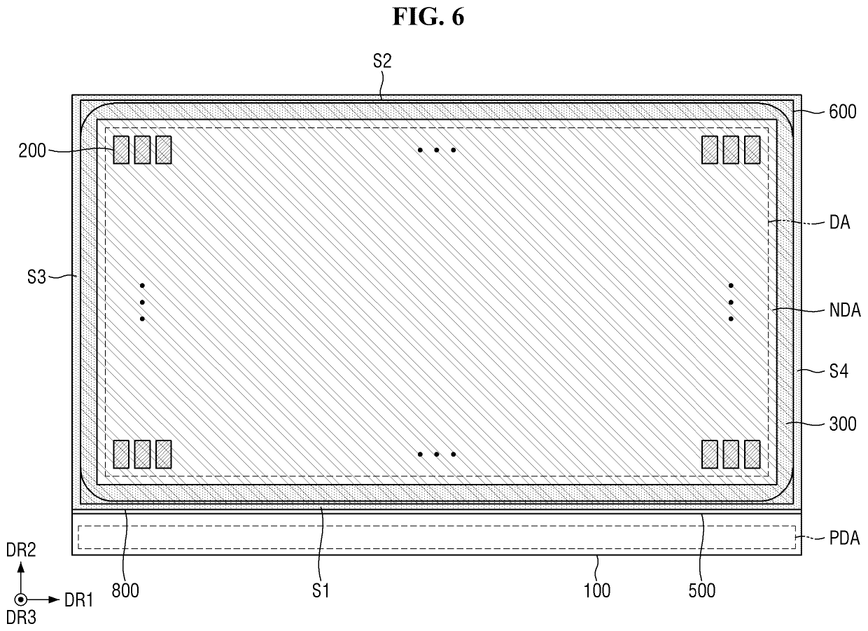

Subsequently, as illustrated in FIGS. 6 and 2, a polarization plate 600 may be disposed on the protective substrate 500.

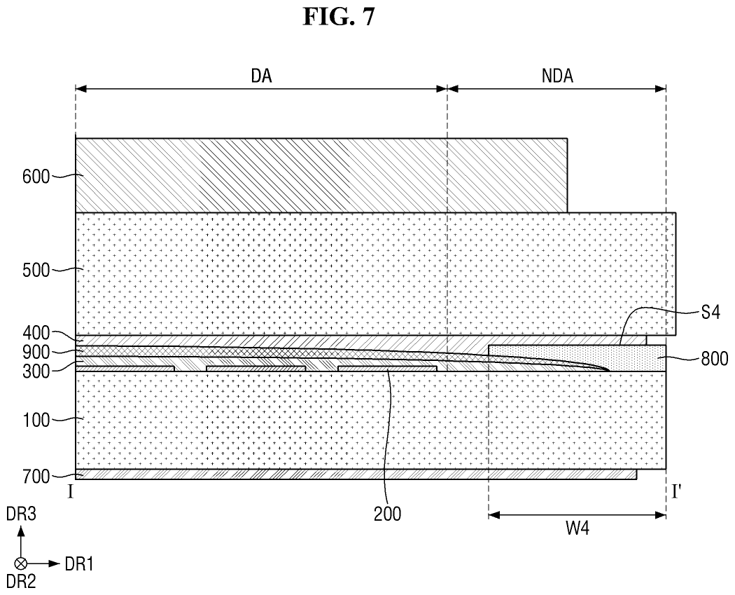

FIG. 7 is schematic cross-sectional view of a display device according to an embodiment, and FIG. 7 may be another cross-sectional view taken along line I-I′ of FIG. 1.

The display device of FIG. 7 is different from the display device of FIG. 2 described above at least in further including a touch sensing unit 900, and the difference will be mainly described as the followings.

As illustrated in FIG. 7, the touch sensing unit 900 may be disposed on the encapsulation layer 300. For example, the touch sensing unit 900 may be disposed between the encapsulation layer 300 and the adhesive layer 400 in the display area DA of the base substrate 100, and may be disposed between the edge of the encapsulation layer 300 and the light shielding layer 800 in the non-display area NDA of the base substrate 100.

The touch sensing unit 900 may be in contact with (or be in direct contact with) the encapsulation layer 300, the light shielding layer 800, and/or the adhesive layer 400. Here, the interface between the touch sensing unit 900 and the light shielding layer 800 may have a round shape.

The touch sensing unit 900 may include one or more touch electrodes for sensing a user's touch in a capacitive manner, and touch lines connecting the touch electrodes to the touch driver. For example, the touch sensing unit 900 may sense the user's touch by using a mutual capacitance method or a self-capacitance method.

For another example, the touch sensing unit 900 may be disposed on a separate substrate disposed on a display area DA of the display device. In this case, the substrate supporting the touch sensing unit 900 may be a base member that encapsulates the display area DA.

The touch electrodes of the touch sensing unit 900 may be disposed in a touch sensor area overlapping the display area DA of the display device. The touch lines of the touch sensing unit 900 may be disposed in a touch peripheral area that overlaps a non-display area NDA of the display device.

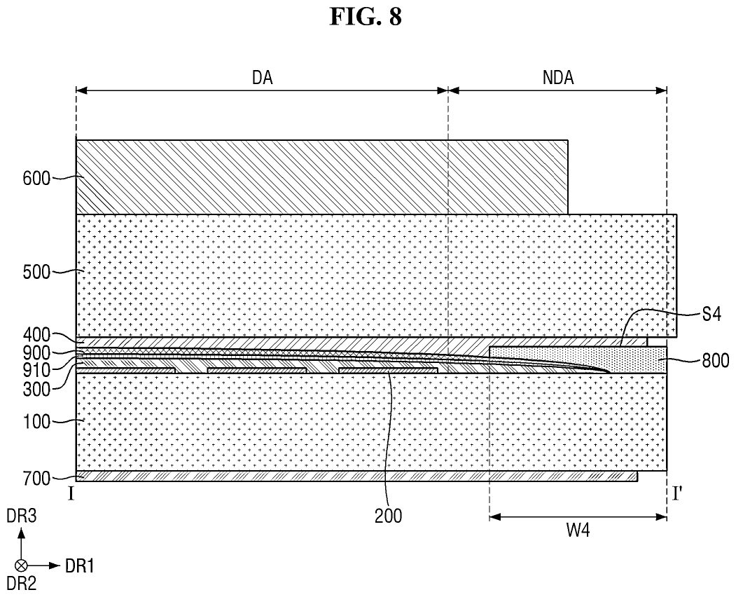

FIG. 8 is a schematic cross-sectional view of a display device according to another embodiment, and FIG. 8 may be another cross-sectional view taken along line I-I′ of FIG. 1.

The display device of FIG. 8 is different from the display device of FIG. 7 described above at least in further including a first planarization layer 910, and the difference will be mainly described as the followings.

As illustrated in FIG. 8, the first planarization layer 910 may be disposed between the encapsulation layer 300 and the touch sensing unit 900.

The first planarization layer 910 may be provided in order to allow a touch electrode and touch lines of the touch sensing unit 900 to be disposed on a planarized surface in the display area DA of the base substrate 100, and such first planarization layer 910 may be formed of a material including at least one of an organic layer or an inorganic layer.

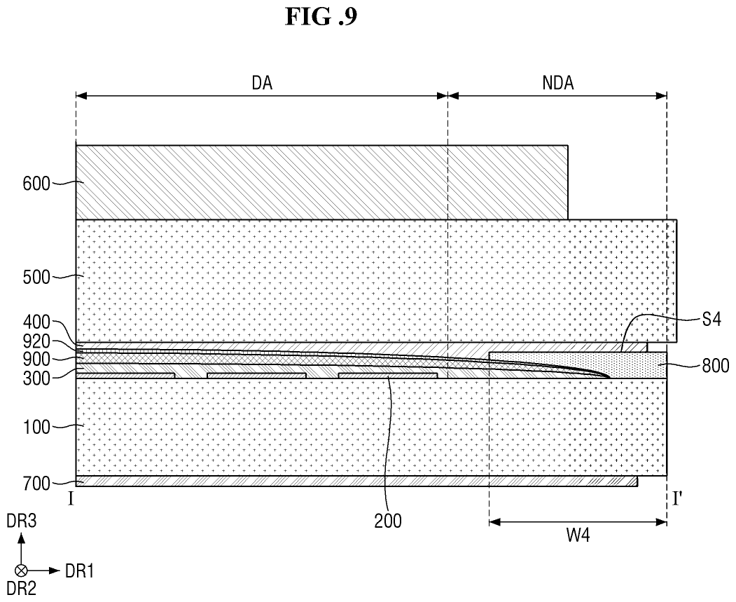

FIG. 9 is a schematic cross-sectional view of a display device according to still another embodiment, and FIG. 9 may be another cross-sectional view taken along line I-I′ of FIG. 1.

The display device of FIG. 9 is different from the display device of FIG. 7 described above at least in further including a second planarization layer 920, and the difference will be mainly described as the followings.

As illustrated in FIG. 9, the second planarization layer 920 may be disposed on the touch sensing unit 900. For example, the second planarization layer 920 may be disposed between the touch sensing unit 900 and the adhesive layer 400 in the display area DA of the base substrate 100, and may be disposed between the edge of the touch sensing unit 900 and the light shielding layer 800 in the non-display area NDA of the base substrate 100.

The second planarization layer 920 may be in contact with (or be in direct contact with) the touch sensing unit 900, the light shielding layer 800, and the adhesive layer 400. Here, the interface between the second planarization layer 920 and the light shielding layer 800 may have a round shape.

The second planarization layer 920 is provided in order to allow the adhesive layer 400 to be disposed on a planarized surface, and such second planarization layer 920 may be formed of a material including at least one of an organic material or an inorganic material.

According to an embodiment, the display device may include both the first and second planarization layers 910 and 920 described above.

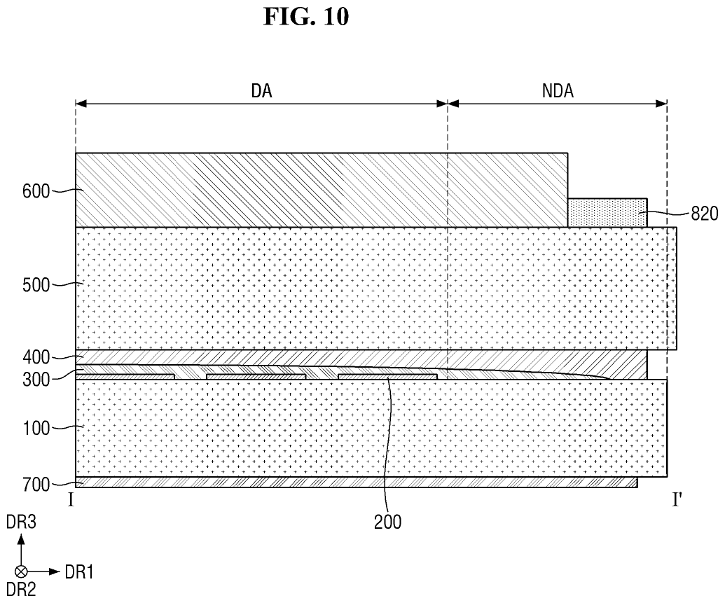

FIG. 10 is a schematic cross-sectional view of a display device according to still another embodiment, and FIG. 10 is another cross-sectional view taken along line I-I′ of FIG. 1.

The display device of FIG. 10 is different from the display device of FIG. 2 described above at least in the position of a light shielding layer 820, and the difference will be mainly described as the followings.

As illustrated in FIG. 10, the light shielding layer 820 may be disposed on the protective substrate 500. For example, the light shielding layer 820 may be disposed on the protective substrate 500 in the non-display area NDA. In other words, in the non-display area NDA, the light shielding layer 820 may be disposed directly on the protective substrate 500. According to an embodiment, in the non-display area NDA, the light shielding layer 820 may be disposed on the protective substrate 500 to surround the edge of the encapsulation layer 300.

In plan view, the light shielding layer 820 may have a closed curve shape (e.g., a square ring shape) surrounding a polarization plate 600. The light shielding layer 820 may be in contact with (or be in direct contact with) the upper surface of the protective substrate 500 and the side surface of the polarization plate 600. The thickness of the light shielding layer 820 may be smaller than the thickness of the polarization plate 600. Here, the thickness of the light shielding layer 820 (or the polarization plate 600) may refer to the dimension in the third direction DR3.

According to an embodiment, the light shielding layer 820 may be disposed on the protective substrate 500 to surround the edge of the encapsulation layer 300.

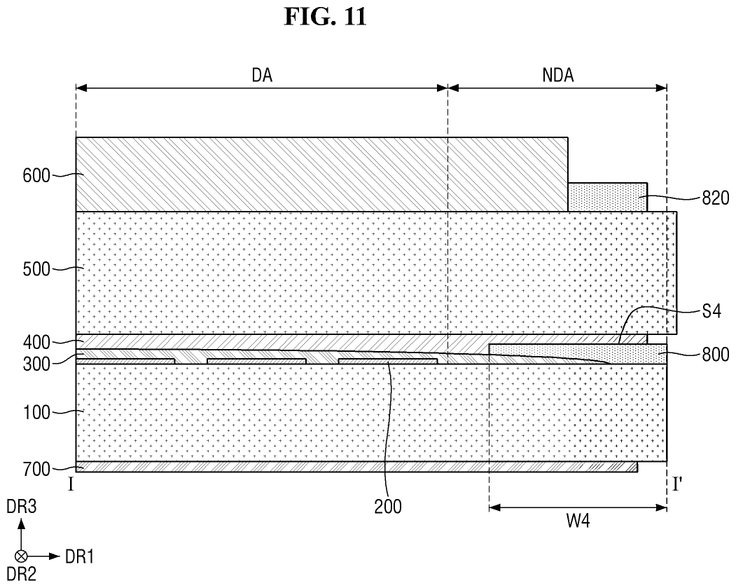

FIG. 11 is a schematic cross-sectional view of a display device according to still another embodiment, and FIG. 11 may be a cross-sectional view taken along line I-I′ of FIG. 1.

The display device of FIG. 11 is different from the display device of FIG. 10 described above at least in including two light shielding layers 800 and 820, and the difference will be mainly described as the followings.

As illustrated in FIG. 11, a light shielding layer 800 (hereinafter, a first light shielding layer 800) may be disposed on the encapsulation layer 300, and another light shielding layer 820 (hereinafter, a second light shielding layer 820) may be disposed on the protective substrate 500. In other words, the first light shielding layer 800 may be substantially identical or similar to the light shielding layer 800 of FIGS. 1 and 2 described above, and the second light shielding layer 820 may be substantially identical or similar to the light shielding layer 820 of FIG. 10 described above. Accordingly, detailed description of the first light shielding layer 800 will be referred to the description related to the light shielding layer 800 of FIGS. 1 and 2 described above, and detailed description of the second light shielding layer 820 will be referred to the description related to the light shielding layer 820 of FIG. 10 described above.

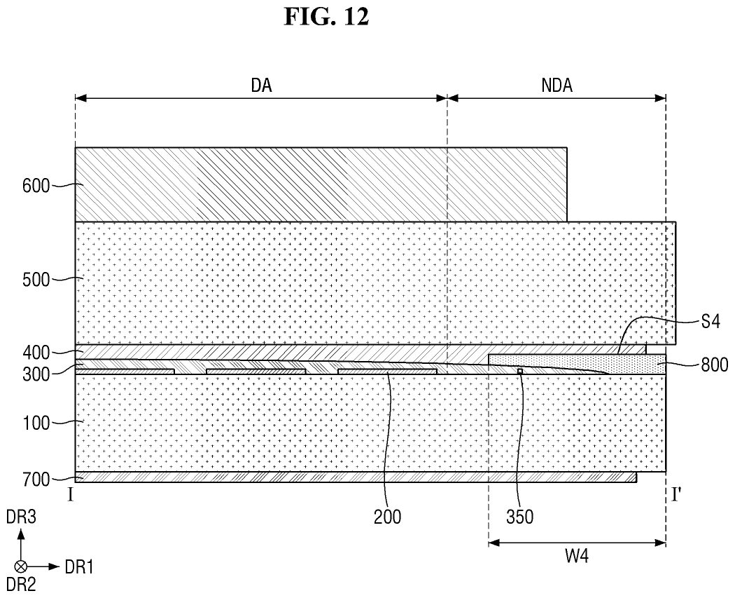

FIG. 12 is a schematic cross-sectional view of a display device according to still another embodiment, and FIG. 12 may be another cross-sectional view taken along line I-I′ of FIG. 1.

The display device of FIG. 12 is different from the display device of FIG. 2 described above in further including a dam 350, and the difference will be mainly described as the followings.

As illustrated in FIG. 12, at least one dam 350 may be disposed in the non-display area NDA of the base substrate 100. In plan view, the dam 350 may have a closed curve shape surrounding the display area DA.

The encapsulation layer 300 may be disposed on the display elements 200 and the dam 350.

According to an embodiment, the dam 350 may be disposed in the non-display area NDA to overlap the light shielding layer 800 in the non-display area NDA of the base substrate 100.

In the process of forming the encapsulation layer 300, the dam 350 can prevent a material of the encapsulation layer 300 from permeating into a pad area PDA of the base substrate 100. For example, the encapsulation layer 300 may include a first inorganic layer, an organic layer, and a second inorganic layer stacked in the third direction DR3 on the base substrate 100, and the dam 350 described above can prevent raw material (e.g., a monomer) of an organic layer applied to the base substrate 100 from permeating into the pad area PDA.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a base substrate;
a display element disposed on the base substrate in a display area;
an encapsulation layer on the display element; and
a light shielding layer disposed on the encapsulation layer in a non-display area.

2. The display device of claim 1, wherein the light shielding layer is disposed along the edge of the upper surface of the base substrate and the edge of the upper surface of the encapsulation layer.

3. The display device of claim 1, wherein, in plan view, the light shielding layer surrounds at least one of the encapsulation layer, the display element, and the display area.

4. The display device of claim 3, wherein, in plan view, the light shielding layer has a closed curve shape surrounding at least one of the encapsulation layer, the display element, and the display area.

5. The display device of claim 1, wherein, in a non-display area, the light shielding layer is disposed directly on the encapsulation layer.

6. The display device of claim 5, wherein, in the non-display area, the light shielding layer is in contact with the encapsulation layer.

7. The display device of claim 6, wherein the interface between the light shielding layer and the encapsulation layer has a round shape.

8. The display device of claim 1, further comprising:
an adhesive layer on the encapsulation layer and the light shielding layer.

9. The display device of claim 8, further comprising:
a touch sensing part disposed between the encapsulation layer and the adhesive layer, and disposed between the encapsulation layer and the light shielding layer.

10. The display device of claim 9, wherein the light shielding layer is in contact with the touch sensing part.

11. The display device of claim 9, further comprising:
a first planarization layer between the encapsulation layer and the touch sensing part.

12. The display device of claim 9, further comprising:
a second planarization layer between the touch sensing part and the adhesive layer, and disposed between the touch sensing part and the light shielding layer.

13. The display device of claim 8, further comprising:
a protective substrate on the adhesive layer.

14. The display device of claim 9, further comprising:
a polarization plate on the protective substrate.

15. The display device of claim 14, wherein the light shielding layer is disposed on the protective substrate to overlap the edge of the encapsulation layer.

16. The display device of claim 15, wherein the light shielding layer is disposed directly on the protective substrate.

17. The display device of claim 15, wherein, in plan view, the light shielding layer surrounds the polarization plate.

18. The display device of claim 15, wherein the light shielding layer comprises:
a first light shielding layer disposed directly on the encapsulation layer; and
a second light shielding layer disposed directly on the protective substrate to overlap the encapsulation layer.

19. The display device of claim 1, further comprising:
a dam disposed on the base substrate to overlap the light shielding layer in the non-display area.

20. The display device of claim 19, wherein a portion of the encapsulation layer is disposed between the dam and the light shielding layer.

21. The display device of claim 1, wherein the light shielding layer includes a black pigment or an organic black pigment.

22. The display device of claim 1, wherein the light shielding layer has a square ring shape with four sides.

23. The display device of claim 22, wherein the four sides comprise:
a first side adjacent to a pad area of the base substrate;
a second side disposed to face the first side;
a third side connected to an end of the first side and an end of the second side; and
a fourth side disposed to face the third side, and connected to another end of the first side and another end of the second side.

24. The display device of claim 23, wherein
a width of the first side and a width of the second side are substantially equal to each other, and
a width of the third side and a width of the fourth side are different.

25. A method for fabricating a display device, the method comprising:
placing a display element on a base substrate in a display area;
placing an encapsulation layer on the display element; and
placing a light shielding layer on the encapsulation layer in a non-display area.

26. The method of claim 25, wherein the light shielding layer is disposed along the edge of the upper surface of the base substrate and the edge of the upper surface of the encapsulation layer.

27. The method of claim 25, wherein, in plan view, the light shielding layer surrounds at least one of the encapsulation layer, the display element, and the display area.

28. The method of claim 27, wherein, in plan view, the light shielding layer has a closed curve shape surrounding at least one of the encapsulation layer, the display element, and the display area.

29. The method of claim 25, wherein, in the non-display area, the light shielding layer is disposed directly on the encapsulation layer.

30. The method of claim 29, wherein, in the non-display area, the light shielding layer is in contact with the encapsulation layer.

31. The method of claim 30, wherein the interface between the light shielding layer and the encapsulation layer has a round shape.
